(19) United States
(12) Patent Application Publication
(10) Pub. No.: US 2025/0364199 A1
(43) Pub. Date: Nov. 27, 2025

(54) ELECTRON SOURCE

(71) Applicant: Kabushiki Kaisha Toshiba, Tokyo (JP)

(72) Inventors: Hisao MIYAZAKI, Yokohama Kanagawa (JP); Shigeya KIMURA, Yokohama Kanagawa (JP); Shinya NUNOUE, Ichikawa Chiba (JP)

(21) Appl. No.: 19/061,834

(22) Filed: Feb. 24, 2025

(30) Foreign Application Priority Data
May 24, 2024 (JP) 2024-084808

(51) Int. Cl. H01J 1/308; H01J 37/06

(52) U.S. Cl. CPC H01J 1/308; H01J 37/06; H01J 2201/3048

(57) ABSTRACT

According to one embodiment, an electron source includes a first member. The first member includes a first region and a second region. The first region includes InₓAl_{y}Ga_{1-x-y}N (0≤x≤1, 0≤y≤1, x+y≤1). The second region includes diamond including boron.

### CROSS-REFERENCE TO RELATED APPLICATIONS

This application is based upon and claims the benefit of priority from Japanese Patent Application No. 2024-084808, filed on May 24, 2024; the entire contents of which are incorporated herein by reference.

### FIELD

Embodiments described herein relate generally to an electron source.

### BACKGROUND

For example, electrons emitted from an electron source are applied to electronic devices such as electronic drawing devices. It is desired to improve the characteristics of electron sources.

### BRIEF DESCRIPTION OF THE DRAWINGS

FIG. 1 is a schematic cross-sectional view illustrating an electron source according to a first embodiment;

FIG. 2 is a schematic diagram illustrating the electron source according to the first embodiment;

FIG. 3 is a schematic cross-sectional view illustrating the electron source according to the first embodiment;

FIG. 4 is an electron micrograph image illustrating an electron source according to the first embodiment;

FIG. 5 is a schematic diagram illustrating the electron source according to the first embodiment;

FIG. 6 is a graph illustrating an electron source;

FIG. 7 is a graph illustrating an electron source; and

FIGS. 8A and 8B are schematic diagrams illustrating the electron source according to the first embodiment.

### DETAILED DESCRIPTION

According to one embodiment, an electron source includes a first member. The first member includes a first region and a second region. The first region includes InₓAl_{y}Ga_{1-x-y}N (0≤x≤1, 0≤y≤1, x+y≤1). The second region includes diamond including boron.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

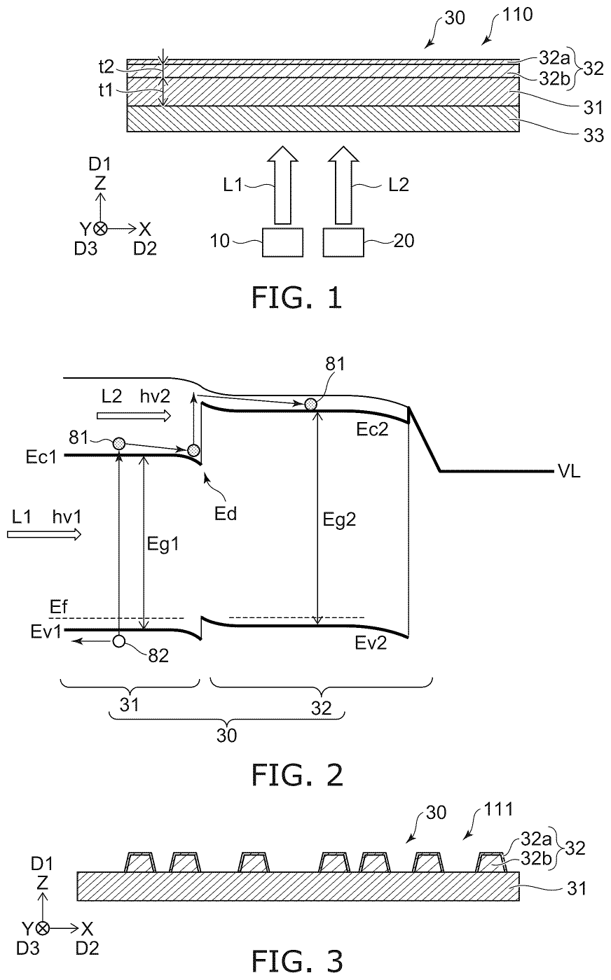

FIG. 1 is a schematic cross-sectional view illustrating an electron source according to a first embodiment.

As shown in FIG. 1, an electron source 110 according to the embodiment includes a first member 30. The first member 30 includes a first region 31 and a second region 32.

A direction from the first region 31 to the second region 32 is defined as a first direction D1. The first direction D1 is a Z-axis direction. One direction perpendicular to the Z-axis direction is defined as an X-axis direction (for example, second direction D2). A direction perpendicular to the Z-axis direction and the X-axis direction is defined as a Y-axis direction (for example, third direction D3).

The first region 31 is, for example, layer-like (or film-like) along the X-Y plane. The second region 32 may not be a homogeneous film. As described later, the second region 32 may have an island shape or a mesh shape.

The first region 31 includes nitride. The first region 31 includes, for example, nitride including Ga. The first region 31 includes, for example, InₓAl_{y}Ga_{1-x-y}N (0≤x≤1, 0≤y≤1, x+y≤1). The first region 31 may include, for example, AlGaN or InGaN.

The second region 32 includes a diamond. The diamond may include boron.

In one example, electrons are emitted from the second region 32 by irradiating the first member 30 with light (for example, at least one of a first light L1 or a second light L2). The second region 32 is an electron emission region.

When light enters the first region 31, movable electrons are generated in the first region 31. The electrons move to the second region 32 and are emitted from the surface of the second region 32 to the outside. The first region 31 is a light absorption region. The first region 31 supports the emission of electrons from the second region 32, for example.

For example, there is a reference example including a silicon carbide film and a diamond film. In the reference example, electrons pass through the diamond film by tunnel effect. High energy (high electric field strength) is required to obtain the tunnel effect, which is impractical.

In the embodiment, the first region 31 of nitride and the second region 32 of diamond are combined. Thereby, electrons can be supplied from the first region 31 to the second region 32 using relatively low energy (for example, light). This results in highly efficient electron emission. According to embodiments, an electron source with improved characteristics is provided.

For example, the second region 32 may include boron. In this case, the second region 32 becomes p-type. This results in higher efficiency. In embodiments, second region 32 may include nitrogen.

FIG. 2 is a schematic diagram illustrating the electron source according to the first embodiment.

FIG. 2 illustrates the energy in the first member 30. As shown in FIG. 2, the first region 31 has a first conduction band energy Ec1 of a first conduction band and a first valence band energy Ev1 of a first valence band. The difference between the first conduction band energy Ec1 and the first valence band energy Ev1 corresponds to a first band gap energy Eg1 of the first region 31. The second region 32 has a second conduction band energy Ec2 of the second conduction band and a second valence band energy Ev2 of the second valence band. The difference between the second conduction band energy Ec2 and the second valence band energy Ev2 corresponds to a second bandgap energy Eg2 of the second region 32. The first region 31 is in contact with the second region 32, and the Fermi level Ef in the first region 31 is the same as the Fermi level in the second region 32.

For example, by the first light L1 being incident on the first region 31, movable carriers (electrons 81 and holes 82) are generated in the first region 31. The electrons 81 are excited by the first light L1 to move to the second region 32. In a case where a work function of the first region 31 is larger than a work function of the second region 32, a local valley Ed of energy is formed between the first region 31 and the second region 32. The electrons 81 gather in the valley Ed. Furthermore, when the first member 30 is irradiated with the second light L2, the electrons gathered in the valley Ed can move to the second region 32 over the barrier between the first region 31 and the second region 32. The electrons 81 that have moved to the second region 32 are emitted to the outside. For example, the electrons 81 are emitted toward the space of a vacuum level VL.

Thus, higher efficiency can be obtained in the case where the second region 32 includes boron. This is considered to be based on the feature that the local valley Ed of energy is formed between the first region 31 and the second region 32. For example, the second region 32 being p-type provides higher efficiency.

The first light L1 has a first peak wavelength. The second light L2 has a second peak wavelength. The second peak wavelength is different from the first peak wavelength. For example, the first energy hv1 of the first light L1 is larger than the first band gap energy Eg1. For example, the second energy hv2 of the second light L2 is larger than the absolute value of the difference between the first conduction band energy Ec1 and the second conduction band energy Ec2.

In the embodiment, a concentration of boron in the second region 32 may be, for example, not less than 1×10¹⁶ cm⁻³ and not more than 1×10²² cm⁻³. P-type characteristics can be stably obtained.

In the embodiment, the first region 31 may include boron. For example, a part of the boron elements introduced into the second region 32 may move to the first region 31 by diffusion or the like.

In the embodiment, the first region 31 may include magnesium (Mg). The first region 31 is, for example, p-type. For example, the energy of the valence band becomes close to the Fermi level Ef, and the energy distribution illustrated in FIG. 2 is effectively formed. Electrons can be emitted with high efficiency. In the embodiment, a concentration of Mg in the first region 31 may be, for example, not less than 1×10¹⁶ cm⁻³ and not more than 1×10²² cm⁻³.

In the embodiment, the first region 31 may include at least one selected from the group consisting of boron and magnesium.

As shown in FIG. 2, the first bandgap energy Eg1 of the first region 31 may be smaller than the second bandgap energy Eg2 of the second region 32. The carriers in the first region 31 can be excited by the first light L1 having relatively low energy.

The second region 32 may be in contact with the first region 31. As shown in FIG. 1, a second thickness t2 of the second region 32 may be thinner than a first thickness t1 of the first region 31. Electrons can be emitted with higher efficiency. In one example, the second thickness t2 is less than 1000 nm. The first thickness t1 is not less than 10 nm and not more than 1000 nm. For example, the second thickness t2 may be less than 10 nm. The first thickness t1 may be not less than 10 nm and not more than 100 nm. As described later, the second region 32 may have an island shape or a mesh shape. In this case, the second thickness t2 may be an average thickness.

In the embodiment, at least a part of the second region 32 may include hydrogen. For example, the surface of the second region 32 may be hydrogen-terminated. More stable characteristics can be obtained.

As shown in FIG. 1, for example, the second region 32 may include a surface region 32a and a non-surface region 32b. The non-surface region 32b is provided between the first region 31 and the surface region 32a. The surface region 32a includes carbon and hydrogen. The non-surface region 32b does not include hydrogen. Alternatively, a concentration of hydrogen in the non-surface region 32b is lower than a concentration of hydrogen in the surface region 32a.

As shown in FIG. 1, the first member 30 may further include a third region 33. The first region 31 is provided between the third region 33 and the second region 32. The third region 33 includes Al and N, for example. The third region 33 may further include Ga. An Al composition ratio in the third region 33 may be higher than an Al composition ratio in the first region 31. By providing the third region 33, for example, a mismatch in lattice constant with the substrate (for example, sapphire) is alleviated. For example, it is easy to obtain high crystallinity in the first region 31. For example, an electron affinity of the third region 33 may be greater than an electron affinity of the first region 31. For example, electrons are more likely to be transported in the direction from the first region 31 to the second region 32.

In addition to the first member 30, the electron source 110 may include at least one of the first light emitting portion 10 or the second light emitting portion 20. The first light emitting portion 10 is configured to cause the first light L1 to be incident on the first member 30. The second light emitting portion 20 is configured to cause the second light L2 to be incident on the first member 30.

In the embodiment, the boron amount of boron in the second region 32 may be less than 1 x10¹⁸ cm⁻². The dose amount of boron in the first region 31 may be less than 1×10¹⁸ cm⁻². The dose amount of Mg in the first region 31 may be not less than 1×10¹⁰ cm⁻² and not more than 1×10¹⁸ cm⁻².

FIG. 3 is a schematic cross-sectional view illustrating the electron source according to the first embodiment.

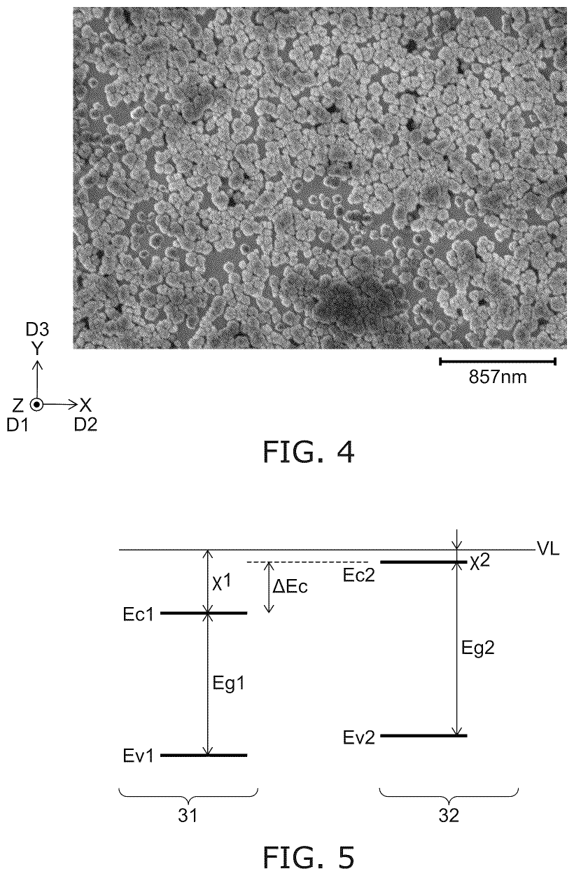

FIG. 4 is an electron micrograph image illustrating an electron source according to the first embodiment.

As shown in FIG. 3, in an electron source 111 according to the embodiment, the second region 32 has an island shape or a mesh shape. The configuration of the electron source 111 except for this may be the same as the configuration of the electron source 110.

In the electron source 111, a large surface area is obtained in the second region 32 due to the island-like or mesh-like second region 32. Electrons can be emitted with higher efficiency. For example, a part of the first region 31 is not covered by the second region 32. For example, the second region 32 is provided on a part of the first region 31.

In the example shown in FIG. 4, the second region 32 has an island shape. A plurality of independent island regions are provided. In the embodiment, at least a part of the second region 32 may be a continuous region including holes. Side faces of the pores provide a large surface area.

FIG. 5 is a schematic diagram illustrating the electron source according to the first embodiment.

FIG. 5 illustrates the energy in a state where the first region 31 is not in contact with the second region 32. The first region 31 has the first conduction band energy Ec1 of the first conduction band and the first valence band energy Ev1 of the first valence band. The difference between the first conduction band energy Ec1 and the first valence band energy Ev1 corresponds to the first band gap energy Eg1 of the first region 31.

The second region 32 has the second conduction band energy Ec2 of the second conduction band and the second valence band energy Ev2 of the second valence band. The difference between the second conduction band energy Ec2 and the second valence band energy Ev2 corresponds to the second bandgap energy Eg2 of the second region 32.

The first conduction band energy Ec1 is lower than the second conduction band energy Ec2. A first difference between the first conduction band energy Ec1 and the second conduction band energy Ec2 corresponds to an energy difference ΔEc.

A difference between the vacuum level VL and the first conduction band energy Ec1 is defined as a first energy difference χ1. A difference between the vacuum level VL and the second conduction band energy Ec2 is defined as a second energy difference χ2. The first energy difference χ1 is larger than the second energy difference χ2. The difference between the first energy difference χ1 and the second energy difference χ2 corresponds to the energy difference ΔEc.

In the embodiment, the first bandgap energy Eg1 is smaller than the second bandgap energy Eg2. Electrons 81 are excited in the first region 31 by the first energy hv1 of the first light L1.

For example, in the embodiment, a sum (χ1+Eg1) of the first energy difference χ1 between the vacuum level VL and the first conduction band energy Ec1 of the first region 31, and the first band gap energy Eg1 is defined as a first sum. A sum (χ2+Eg2) of the second energy difference χ2 between the vacuum level VL and the second conduction band energy Ec2 of the second region 32, and the second band gap energy Eg2 is defined as a second sum. In the embodiment, the first sum (χ1+Eg1) is preferably larger than the second sum (χ2+Eg2). For example, the first valence band energy Ev1 of the first region 31 is lower than the second valence band energy Ev2 of the second region 32. Thereby, the band structure described with respect to FIG. 2 can be obtained when the first region 31 contacts the second region 32.

For example, the absolute value of the first difference (energy difference ΔEc) between the first conduction band energy Ec1 and the second conduction band energy Ec2 is smaller than the first band gap energy Eg1. For example, by the second energy hv2 of the second light L2, the electrons 81 move from the first region 31 to the second region 32 over the barrier of the first difference (energy difference ΔEc). The second energy hv2 of the second light L2 may be smaller than the first bandgap energy Eg1.

Thus, the first energy hv1 of the first light L1 is larger than the first bandgap energy Eg1. The second energy hv2 of the second light L2 is larger than the absolute value of the first difference (energy difference ΔEc). The first energy hv1 is greater than the second energy hv2. By using such two lights with different energies, electrons can be emitted from the first member 30 with high efficiency.

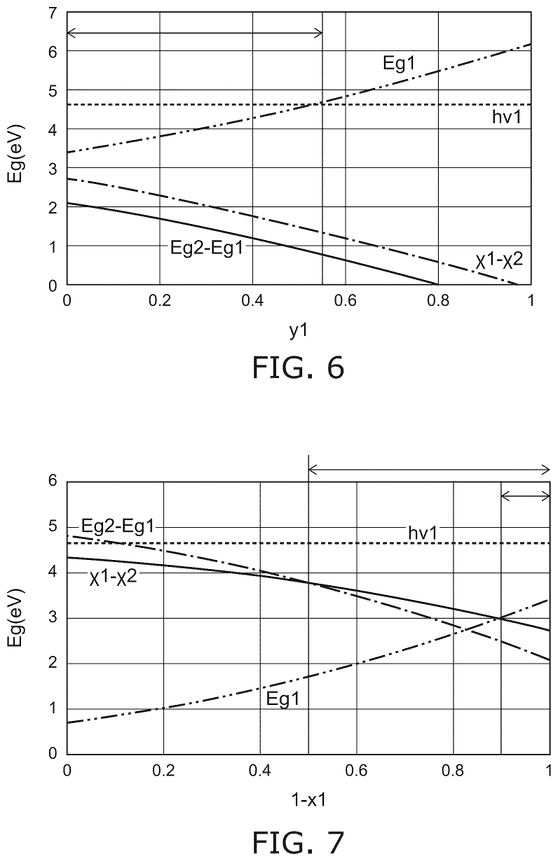

FIG. 6 is a graph illustrating an electron source.

FIG. 6 illustrates various energies when the composition ratio y1 is changed in a case where the first region 31 includes Al_{y1}Ga_{1-y1}N (0≤y1≤1). The second region 32 is diamond including boron. In FIG. 6, the first band gap energy Eg1, the difference (Eg2−Eg1) between the second band gap energy Eg2 and the first band gap energy Eg1, and the difference (χ1−χ2) between the first energy difference χ1 and the second energy difference χ2 are exemplified. As an example, the value of the first energy hv1 is shown when the first light L1 having a wavelength of 266 nm is used.

As shown in FIG. 6, when the composition ratio y1 is 0.54 or less, the first band gap energy Eg1 is lower than the first energy hv1. In the case where the first region 31 includes Al_{y1}Ga_{1-y1}N, it is preferable that the first region 31 includes Al_{y1}Ga_{1-y1}N (0≤y1<0.54).

In this example, the second energy hv2 is greater than the difference (χ1−χ2). The second energy hv2 may be smaller than the first bandgap energy Eg1.

FIG. 7 is a graph illustrating an electron source.

FIG. 7 illustrates various energies when the composition ratio “1-x1” is changed in a case where the first region 31 includes Inₓ₁Ga₁₋ₓ₁N (0≤x1≤1). The composition ratio “1−x1” is the composition ratio of Ga. The second region 32 is diamond including boron. In FIG. 7, the first band gap energy Eg1, the difference (Eg2-Eg1) between the second band gap energy Eg2 and the first band gap energy Eg1, and the difference (χ1−χ2) between the first energy difference χ1 and the second energy difference χ2 are exemplified. As an example, the value of the first energy hv1 is shown when the first light L1 having a wavelength of 266 nm is used.

As shown in FIG. 7, when the composition ratio “1−x1” is higher than 0.9, the first band gap energy Eg1 becomes larger than the difference (χ1−χ2). That is, when the composition ratio x1 is lower than 0.1, the first band gap energy Eg1 becomes larger than the difference (χ1−χ2). In the case where the first region 31 includes Inₓ₁Ga₁₋ₓ₁N, it is preferable that the first region 31 includes Inₓ₁Ga₁₋ₓ₁N (0≤x1<0.1). The first region 31 may include Inₓ₁Ga₁₋ₓ₁N (0≤x1<0.5).

In the embodiment, for example, it is preferable that the following first formula is satisfied.

$$0 < Eg 2 - Eg 1 < {X}^{1} - {X}^{2} < Eg 1 \qquad ( 1 )$$

In the embodiment, for example, it is preferable that the following second formula is satisfied.

$$0 < Eg 2 - Eg 1 < {X}^{1} - {X}^{2} < Eg 1 < hv 1 \qquad ( 2 )$$

In the embodiment, for example, it is preferable that the following third equation is satisfied.

$$0 < Eg 2 - Eg 1 < {X}^{1} - {X}^{2} < hv 2 < Eg 1 < hv 1 \qquad ( 3 )$$

In embodiments, the Fermi level may be considered to be substantially the same as the valence band energy. In the embodiment, the first work function of the first region 31 may be larger than the second work function of the second region 32.

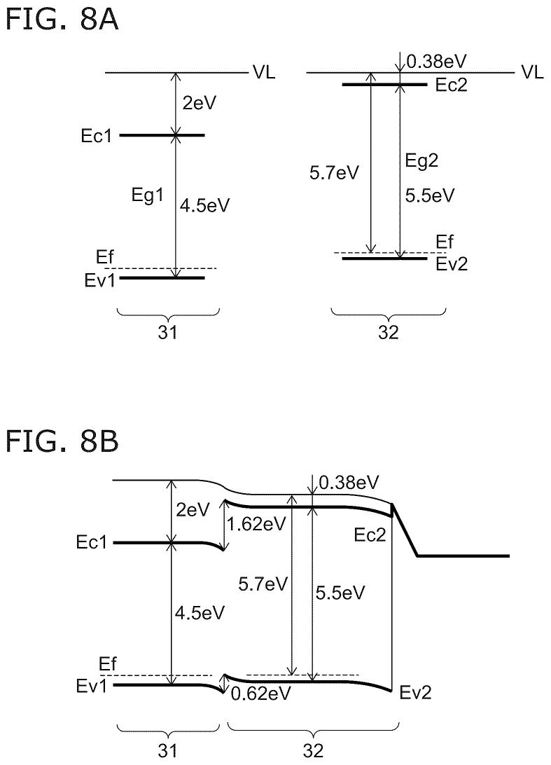

FIGS. 8A and 8B are schematic diagrams illustrating the electron source according to the first embodiment.

These figures correspond to the case where the first region 31 includes p-type Al_{0.4}Ga_{0.6}N and the second region 32 includes p-type diamond. FIG. 8A illustrates a state in which the first region 31 is not in contact with the second region 32. FIG. 8B illustrates a state in which the first region 31 is in contact with the second region 32. As shown in FIG. 8B, the local valley Ed of energy is formed between the first region 31 and the second region 32. Highly efficient electron emission can be obtained. As shown in FIG. 8B, the vacuum level VL is lowered due to the C—H dipole existing on the surface of the second region 32. Highly efficient electron emission can be obtained.

### Second Embodiment

The second embodiment relates to an electronic device. The electronic device includes the electron source (for example, the electron source 110 or the electron source 111) according to the first embodiment. The electronic device may include, for example, at least one selected from the group consisting of a sensor, a switch device, an electron beam lithography device, a processing device, or an analysis device. An electronic device whose characteristics can be improved is provided. The sensor may include, for example, a light sensor. The analysis device may include, for example, an electron microscope.

Information regarding length and thickness can be obtained by electron microscopy, etc. Information regarding the composition of the material can be obtained by SIMS (Secondary Ion Mass Spectrometry), EDX (Energy dispersive X-ray spectroscopy), or the like. Based on information regarding the composition of the material, information regarding the energy of the material can be obtained.

The embodiments may include the following Technical proposals:

### Technical Proposal 1

An electron source, comprising:
a first member,
the first member including
a first region including InₓAl_{y}Ga_{1-x-y}N (0≤x≤1, 0≤y≤1, x+y≤1), and
a second region including diamond including boron.

### Technical Proposal 2

The electron source according to Technical proposal 1, wherein
a concentration of boron in the second region is not less than 1×10¹⁶ cm⁻³ and not more than 1×10²² cm⁻³.

### Technical Proposal 3

The electron source according to Technical proposal 1 or 2, wherein
the first region includes at least one selected from the group consisting of boron and magnesium.

### Technical Proposal 4

The electron source according to Technical proposal 3, wherein
the first region includes magnesium, and
a concentration of magnesium in the first region is 1×10¹⁶ cm⁻³ and not more than 1×10²² cm⁻³.

### Technical Proposal 5

The electron source according to any one of Technical proposals 1-4, wherein
the second region includes nitrogen.

### Technical Proposal 6

The electron source according to any one of Technical proposals 1-5, wherein
the second region is in an island shape or a mesh shape.

### Technical Proposal 7

The electron source according to any one of Technical proposals 1-6, wherein
a part of the first region is not covered by the second region.

### Technical Proposal 8

The electron source according to any one of Technical proposals 1-7, wherein
at least a part of the second region includes hydrogen.

### Technical Proposal 9

The electron source according to any one of Technical proposals 1-8, wherein
the second region includes a surface region and a non-surface region,
the non-surface region is provided between the first region and the surface region,
the surface region includes carbon and hydrogen, and
the non-surface region does not include hydrogen, or a concentration of hydrogen in the non-surface region is lower than a concentration of hydrogen in the surface region.

### Technical Proposal 10

The electron source according to any one of Technical proposals 1-9, wherein
the second region is in contact with the first region.

### Technical Proposal 11

The electron source according to any one of Technical proposals 1-10, wherein
a second thickness of the second region is less than a first thickness of the first region.

### Technical Proposal 12

The electron source according to any one of Technical proposals 1-10, wherein
a second thickness of the second region is less than 1000 nm, and
a first thickness of the first region is not less than 10 nm and not more than 1000 nm.

### Technical Proposal 13

The electron source according to any one of Technical proposals 1-12, wherein
the first region includes Al_{y1}Ga_{1-y1}N (0≤y1<0.54).

### Technical Proposal 14

The electron source according to any one of Technical proposals 1-12, wherein
the first region includes Inₓ₁Ga₁₋ₓ₁N (0≤x1<0.5).

### Technical Proposal 15

The electron source according to any one of Technical proposals 1-14, wherein
when the first member is irradiated with light, electrons are emitted from the second region.

### Technical Proposal 16

An electron source, comprising:
a first member,
the first member including a first region and a second region,
a first band gap energy of the first region being smaller than a second band gap energy of the second region, and
a first work function of the first region being larger than a second work function of the second region.

### Technical Proposal 17

The electron source according to Technical proposal 16, wherein
a first sum is greater than a second sum,
the first sum is a sum of the first band gap energy and a first energy difference between a vacuum level and a first conduction band energy of the first region, and
the second sum is a sum of second band gap energy and a second energy difference between the vacuum level and a second conduction band energy of the second region.

### Technical Proposal 18

The electron source according to Technical proposal 17, wherein
an absolute value of a first difference between the first conduction band energy and the second conduction band energy is smaller than the first band gap energy.

### Technical Proposal 19

The electron source according to Technical proposal 18, further comprising:
a first light emitting portion configured to emit a first light having a first peak wavelength into the first member, and
a first energy of the first light is greater than the first band gap energy.

### Technical Proposal 20

The electron source according to Technical proposal 19, further comprising:
a second light emitting portion configured to emit a second light having a second peak wavelength into the first member, and
a second energy of the second light is greater than the absolute value of the first difference.

According to an embodiment, an electron source is provided that can improve its characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the electron sources such as members, the light-emitting portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electron sources practicable by an appropriate design modification by one skilled in the art based on the electron sources described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electron source, comprising:
a first member,
the first member including
a first region including InₓAl_{y}Ga_{1-x-y}N (0≤x≤1, 0≤y≤1, x+y≤1), and
a second region including diamond including boron.

2. The electron source according to claim 1, wherein
a concentration of boron in the second region is not less than 1×10¹⁶ cm⁻³ and not more than 1×10²² cm⁻³.

3. The electron source according to claim 1, wherein
the first region includes at least one selected from the group consisting of boron and magnesium.

4. The electron source according to claim 3, wherein
the first region includes magnesium, and
a concentration of magnesium in the first region is 1×10¹⁶ cm⁻³ and not more than 1×10²² cm⁻³.

5. The electron source according to claim 1, wherein
the second region includes nitrogen.

6. The electron source according to claim 1, wherein
the second region is in an island shape or a mesh shape.

7. The electron source according to claim 1, wherein
a part of the first region is not covered by the second region.

8. The electron source according to claim 1, wherein
at least a part of the second region includes hydrogen.

9. The electron source according to claim 1, wherein
the second region includes a surface region and a non-surface region,
the non-surface region is provided between the first region and the surface region,
the surface region includes carbon and hydrogen, and
the non-surface region does not include hydrogen, or a concentration of hydrogen in the non-surface region is lower than a concentration of hydrogen in the surface region.

10. The electron source according to claim 1, wherein
the second region is in contact with the first region.

11. The electron source according to claim 1, wherein
a second thickness of the second region is less than a first thickness of the first region.

12. The electron source according to claim 1, wherein
a second thickness of the second region is less than 1000 nm, and
a first thickness of the first region is not less than 10 nm and not more than 1000 nm.

13. The electron source according to claim 1, wherein
the first region includes Al_{y1}Ga_{1-y1}N (0≤y1<0.54).

14. The electron source according to claim 1, wherein
the first region includes Inₓ₁Ga₁₋ₓ₁N (0≤x1<0.5).

15. The electron source according to claim 1, wherein
when the first member is irradiated with light, electrons are emitted from the second region.

16. An electron source, comprising:
a first member,
the first member including a first region and a second region,
a first band gap energy of the first region being smaller than a second band gap energy of the second region, and
a first work function of the first region being larger than a second work function of the second region.

17. The electron source according to claim 16, wherein
a first sum is greater than a second sum,
the first sum is a sum of the first band gap energy and a first energy difference between a vacuum level and a first conduction band energy of the first region, and
the second sum is a sum of second band gap energy and a second energy difference between the vacuum level and a second conduction band energy of the second region.

18. The electron source according to claim 17, wherein
an absolute value of a first difference between the first conduction band energy and the second conduction band energy is smaller than the first band gap energy.

19. The electron source according to claim 18, further comprising:
a first light emitting portion configured to emit a first light having a first peak wavelength into the first member, and
a first energy of the first light is greater than the first band gap energy.

20. The electron source according to claim 19, further comprising:
a second light emitting portion configured to emit a second light having a second peak wavelength into the first member, and
a second energy of the second light is greater than the absolute value of the first difference.
